(19) United States
(12) Patent Application Publication
(10) Pub. No.: US 2021/0193053 A1
(43) Pub. Date: Jun. 24, 2021

(54) DISPLAY DEVICE AND ELECTRONIC APPARATUS

(71) Applicant: SEIKO EPSON CORPORATION, Tokyo (JP)

(72) Inventors: Hitoshi OTA, Shiojiri-shi (JP); Takeshi KOSHIHARA, Matsumoto-shi (JP)

(73) Assignee: SEIKO EPSON CORPORATION, Tokyo (JP)

(21) Appl. No.: 17/127,430

(22) Filed: Dec. 18, 2020

(30) Foreign Application Priority Data
Dec. 19, 2019 (JP) 2019-228984

(51) Int. Cl. G09G 3/3275; G09G 3/3233; H01L 27/32

(52) U.S. Cl. CPC G09G 3/3275; G09G 3/3266; H01L 27/3279; G09G 3/3233

(57) ABSTRACT

A display device includes: a display area including a pixel circuit disposed to correspond to an intersection between a scanning line and a data line; a data signal output circuit configured to output a first data signal; and a first capacitive element including one end and the other end, the one end being supplied with the first data signal, and the other end being coupled to the data line, wherein the display area is disposed between the first capacitive element and the data signal output circuit in plan view.

The present application is based on, and claims priority from JP Application Serial Number 2019-228984, filed Dec. 19, 2019, the disclosure of which is hereby incorporated by reference herein in its entirety.

### BACKGROUND

### 1. Technical Field

The present disclosure relates to a display device and an electronic apparatus.

### 2. Related Art

As a display element, for example, a display device using an organic light emitting diode (OLED) is known. In the display device, a pixel circuit including a display element or a transistor is generally provided to correspond to a pixel of an image to be displayed. In such a configuration, a voltage applied via a data line is held by a gate of the transistor and the transistor supplies a current corresponding to the voltage to the display element. Accordingly, the display element emits light with a brightness corresponding to the current. Further, when the display element is a liquid crystal element, the liquid crystal element has a transmittance or a reflectance depending on the voltage held by the gate of the transistor. Further, it is often required to have a smaller display size and display with higher definition in the display device. Since it is necessary to miniaturize the pixel circuit in order to achieve both the smaller display size and the display with higher definition, a technique for integrating a display device on a semiconductor substrate of, for example, silicon has also been proposed.

When the pixel circuit is miniaturized, it is necessary to control a current supplied to a light emitting element in a minute area. The current supplied to the light emitting element is controlled by the voltage between the gate and the source of the transistor, but in the minute area, the current supplied to the light emitting element greatly changes with respect to a slight change in the voltage between the gate and the source. When the display element is a liquid crystal element, the transmittance or the reflectance changes greatly in accordance with a slight change in the voltage applied to the liquid crystal element.

On the other hand, in a data signal output circuit that outputs a signal to a data line, the drive capability thereof is enhanced in order to charge the data line in a short time. In this way, in the data signal output circuit having high drive capability, it is difficult to control the voltage output to the data line with extremely fine accuracy.

Accordingly, a technique in which a coupling capacitive element is provided between a data signal output circuit and a pixel circuit (a data line) and the data signal output circuit outputs a signal to the data line via the capacitive element is proposed (for example, see JP-A-2016-212444). According to this technique, a voltage amplitude of the signal is compressed according to a capacitance ratio between the capacitance of the capacitive element and the parasitic capacitance of the data line and is supplied to the pixel circuit.

However, in the above-described technique, when the data signal output circuit, the capacitive element, and the pixel circuit are provided in that order, the miniaturization can be hindered.

### SUMMARY

A display device according to an aspect of the present disclosure includes: a display area including a pixel circuit disposed to correspond to an intersection between a scanning line and a data line; a data signal output circuit configured to output a first data signal; and a first capacitive element including one end and another en, the one end being supplied with the first data signal, and the other end being coupled to the data line, wherein the display area is disposed between the first capacitive element and the data signal output circuit in a plan view.

### BRIEF DESCRIPTION OF THE DRAWINGS

FIG. 1 is a perspective view showing a configuration of a display device according to an embodiment.

FIG. 2 is a block diagram showing a configuration of the display device.

FIG. 3 is a circuit diagram showing a configuration of a main part of the display device.

FIG. 4 is a diagram showing a configuration of a pixel circuit of the display device.

FIG. 5 is a timing chart showing an operation of the display device.

FIG. 6 is a diagram illustrating an operation of the display device.

FIG. 7 is a diagram illustrating an operation of the display device.

FIG. 8 is a diagram illustrating an operation of the display device.

FIG. 9 is a diagram illustrating an operation of the display device.

FIG. 10 is a plan view showing an arrangement of elements of the display device.

FIG. 11 is a plan view showing an arrangement of a light emitting functional layer and the like of the display device.

FIG. 12 is a partial cross-sectional view of a main part of the display device.

FIG. 13 is a partial cross-sectional view of a main part of the display device.

FIG. 14 is a partial cross-sectional view of a main part of the display device.

FIG. 15 is a partial cross-sectional view of a main part of the display device.

FIG. 16 is a circuit diagram showing a configuration of a main part of a display device according to a first modified example.

FIG. 17 is a plan view showing an arrangement of elements of the display device according to the first modified example.

FIG. 18 is a circuit diagram showing a configuration of a main part of a display device according to a second modified example.

FIG. 19 is a plan view showing an arrangement of elements of the display device according to the second modified example.

FIG. 20 is a perspective view showing a head mounted display using the display device.

FIG. 21 is a diagram showing an optical configuration of the head mounted display.

FIG. 22 is a plan view showing an arrangement of elements in a display device according to a comparative example.

### DESCRIPTION OF EXEMPLARY EMBODIMENTS

Hereinafter, a display device according to an embodiment of the present disclosure will be described with reference to the drawings. In each drawing, the size and scale of each part are made appropriately different from the actual ones. Further, since the embodiments described below are preferred specific examples, various technically preferable limitations are given thereto, but the scope of the present disclosure is not limited to these forms, particularly when the limitation of the present disclosure is not described in the following description.

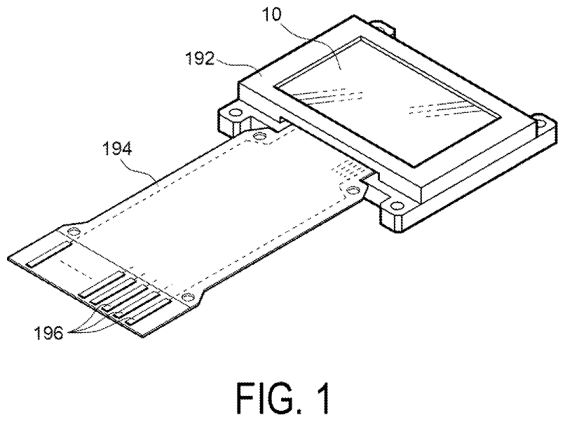

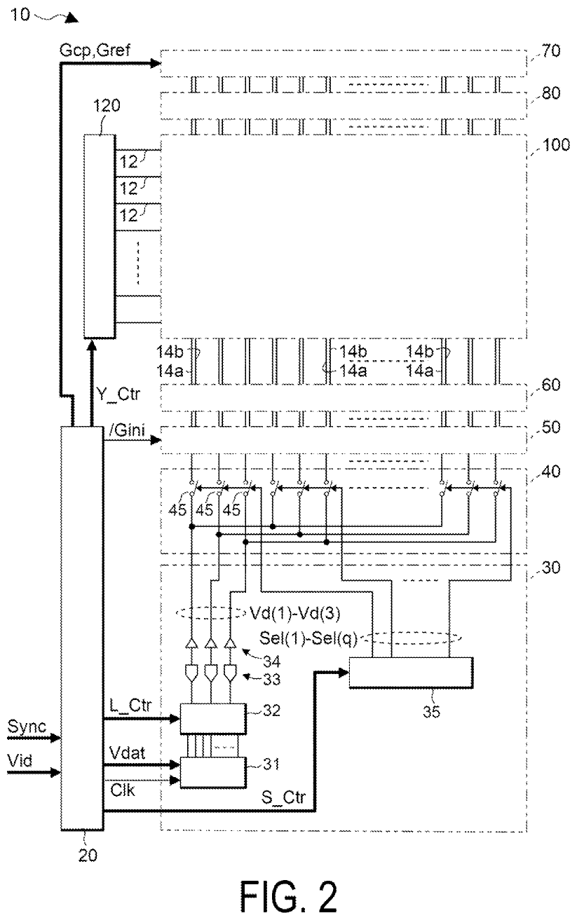

FIG. 1 is a perspective view showing a configuration of a display device 10 according to a first embodiment and FIG. 2 is a block diagram showing a configuration of the display device 10.

This display device 10 is, for example, a micro display panel that displays a color image on a head mounted display or the like and a plurality of pixel circuits or drive circuits that drive the pixel circuits are formed on a semiconductor substrate. The semiconductor substrate is typically a silicon substrate, but may be another semiconductor substrate.

The display device 10 is accommodated in a frame-shaped casing 192 that opens to a display area and one end of a flexible printed circuit (FPC) board 194 is coupled thereto. A plurality of terminals 196 to be coupled to an external host device are provided at the other end of the FPC board 194. Video data, synchronization signals, and the like are supplied to the plurality of terminals 196 via the host device, the plurality of terminals 196, and the FPC board 194.

As shown in FIG. 2, the display device 10 includes a control circuit 20, a data signal output circuit 30, a switch group 40, an initialization circuit 50, a capacitive element group 60, an auxiliary circuit 70, a capacitive element group 80, a display area 100, and a scanning line drive circuit 120.

In the display area 100, m rows of scanning lines 12 are provided in the right and left direction in the figure and 3q columns of data lines 14b are provided in the up and down direction to be electrically insulated from the respective scanning lines 12.

In addition, m and q are integers of 2 or more. Further, as will be described later, pixel circuits are provided to correspond to the intersections of m rows of scanning lines 12 and 3q columns of data lines 14b.

The control circuit 20 controls each unit on the basis of video data Vid or synchronization signals Sync supplied from the host device. The video data Vid supplied in synchronization with the synchronization signal Sync specifies the gradation level of the pixel in the image to be displayed with, for example, 8 bits for each of R, G, and B. Further, synchronization signals Sync include vertical synchronization signals for instructing the start of vertical scanning of video data Vid, horizontal synchronization signals for instructing the start of horizontal scanning, and a dot clock signal indicating the timing of one pixel of video data.

Additionally, the control circuit 20 generates control signals Gcp, Gref, Y_Ctr, /Gini, L_Ctr, and S_Ctr and a clock signal Clk to control each unit. Although not shown in FIG. 2, the control circuit 20 outputs a control signal /Gcp which is in a logical inversion relationship with the control signal Gcp.

Further, the control circuit 20 appropriately processes the video data Vid, up-converts it to, for example, 10 bits, and outputs it as the video data Vdat.

The scanning line drive circuit 120 is a circuit for driving the pixel circuits arranged in m rows and 3q columns in units of one row according to the control signal Y_Ctr. Additionally, as will be described later in detail, the scanning line drive circuit 120 outputs a control signal for controlling a light emitting period to a pixel circuit corresponding to a row and a control signal for resetting a voltage at an anode of an OLED included in the pixel circuit in addition to the scanning signal to the scanning line 12 corresponding to each row.

The data signal output circuit 30 outputs a first data signal. Specifically, the data signal output circuit 30 outputs a first data signal which is a voltage corresponding to a gradation level of a pixel represented by a pixel circuit, that is, a pixel in an image to be displayed and which has not been compressed in voltage amplitude.

Additionally, in this embodiment, the voltage amplitude of the first data signal output from the data signal output circuit 30 is compressed and is supplied to the data line 14b as a second data signal. Thus, the second data signal after compression is also a voltage corresponding to the gradation level of the pixel. In other words, the voltage of the data line 14b is a voltage corresponding to the gradation level of the pixel.

Further, the data signal output circuit 30 also has a function of parallel-converting the serially supplied video data Vdat into a plurality of phases (for example, three phases) and outputting the result.

The data signal output circuit 30 includes a shift register 31, a latch circuit 32, a D/A conversion circuit group 33, an amplifier group 34, and a selection control circuit 35.

The shift register 31 sequentially transfers the video data Vdat that is serially supplied in synchronization with the clock signal Clk and stores the video data for one row, that is, (3q) pieces in terms of the number of pixel circuits.

The latch circuit 32 latches (3q) pieces of video data Vdat stored in the shift register 31 according to the control signal L_Ctr, parallel-converts the latched video data Vdat into three phases according to the control signal L_Ctr, and outputs the result.

The D/A conversion circuit group 33 includes three digital to analog (D/A) converters. The three-phase video data Vdat output from the latch circuit 32 is converted into an analog signal by three D/A converters.

The amplifier group 34 includes three amplifiers. The three-phase analog signal output from the D/A conversion circuit group 33 is amplified by three amplifiers and is output as the first data signals Vd(1), Vd(2), and Vd(3).

The selection control circuit 35 outputs the control signals Sel(1) to Sel(q) which are sequentially and exclusively at the H level before the writing period as will be described later. In this embodiment, the selection control circuit 35 outputs the control signals Sel(1) to Sel(q) which are sequentially and exclusively at the H level in the initialization period and the compensation period of the horizontal scanning period. Additionally, although not shown in FIG. 2, the selection control circuit 35 outputs the control signals /Sel(1) to /Sel(q) that are in a logical inversion relationship with the control signals Sel(1) to Sel(q).

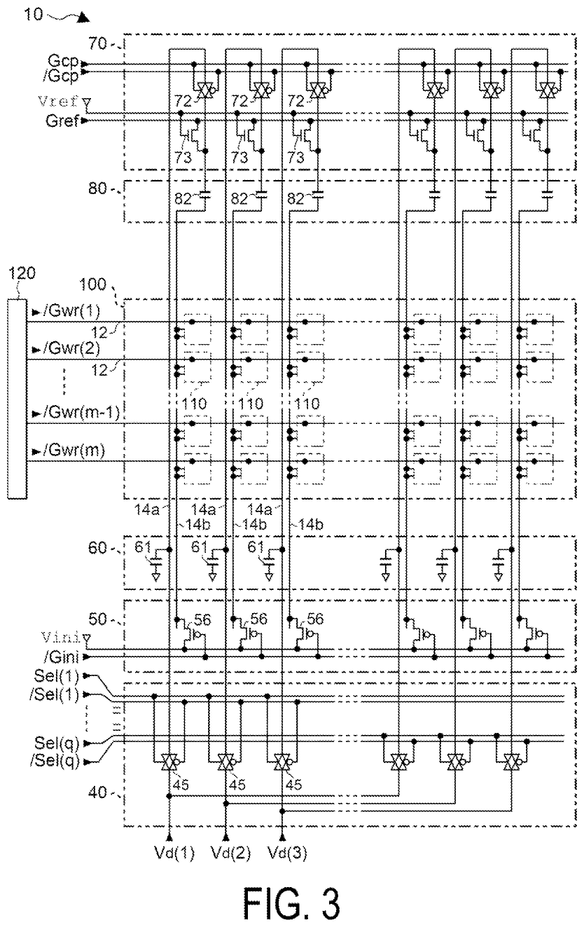

FIG. 3 is a circuit diagram showing the configurations of the switch group 40, the initialization circuit 50, the capacitive element group 60, the auxiliary circuit 70, the capacitive element group 80, and the display area 100 in the display device 10.

The pixel circuits 110 corresponding to the pixels of an image to be displayed are provided in the display area 100 in a matrix. Specifically, the pixel circuits 110 are provided to correspond to the intersections of m rows of scanning lines 12 and (3p) columns of data lines 14b. That is, the pixel circuits 110 are arranged in a matrix with m rows in the vertical direction and (3q) columns in the horizontal direction in the figure. Here, in order to distinguish the rows of the matrix, the rows may be referred to as rows 1, 2, 3, . . . , (m−1), and m from the top in the figure. Similarly, in order to distinguish the columns of the matrix, the columns may be referred to as columns 1, 2, 3, . . . , (3q−1), and (3q) from the left in the figure.

Further, the data lines 14b are grouped in every three columns in this embodiment. Here, if an integer j of 1 or more and q or less is used in order to generalize the group, a total of three columns including the (3j−2)-th column, the (3j−1)-th column, and the (3j)-th column of the data lines 14b belong to the j-th group from the left.

Additionally, three pixel circuits 110 corresponding to the intersections of the scanning lines 12 in the same row and three columns of data lines 14b belonging to the same group correspond to red (R), green (G), and blue (B) pixels and these three pixels represent one dot of the color image to be displayed. That is, in this embodiment, a color of one dot is represented by an additive color mixture by a total of three pixel circuits 110 corresponding to RGB.

The scanning line drive circuit 120 generates a scanning signal for sequentially scanning the scanning lines 12 row by row according to the control signal Y_Ctr. Here, the scanning signals supplied to the scanning lines 12 of the 1st, 2nd, 3rd, . . . , (m−1)-th, and m-th rows are respectively referred to as /Gwr(1), /Gwr(2), . . . , /Gwr(m−1), and /Gwr(m).

Additionally, the scanning line drive circuit 120 generates various control signals synchronized with the scanning signals for each row in addition to the scanning signals /Gwr(1) to /Gwr(m) and supplies the control signals to the display area 100. However, this is not shown in FIG. 2.

In the display device 10, a data transfer line 14a is provided to correspond to the data line 14b.

Further, the switch group 40 is an assembly of a transmission gate 45 provided for each column.

Among them, the input ends of q transmission gates 45 corresponding to columns 1, 4, 7, . . . , and (3q−2) are commonly coupled. Additionally, the first data signal Vd(1) is supplied to this input end in time series for each pixel.

Further, the input ends of q transmission gates 45 corresponding to columns 2, 5, 8, . . . , and (3q−1) are commonly coupled and the first data signal Vd(2) is supplied to each pixel in times series.

Similarly, the input ends of q transmission gates 45 corresponding to columns 3, 6, 9, . . . , and (3q) are commonly coupled and the first data signal Vd(3) is supplied to each pixel in time series.

The output end of the transmission gate 45 of a certain column is coupled to one end of the data transfer line 14a of the corresponding column.

Three transmission gates 45 corresponding to columns (3j−2), (3j−1), and (3j) belonging to the j-th group are turned on between the input end and the output end when the control signal Sel(j) is at the H level (when the control signal/Sel(j) is at the L level).

Additionally, in FIG. 3, only the first group and the q-th group are shown and the other groups are not shown due to space limitations. Further, the transmission gate 45 of FIG. 3 is simply shown as a simple switching element in FIG. 2.

The capacitive element group 60 is an assembly of a capacitive element 61 provided for each column. Here, one end of the capacitive element 61 of a certain column is coupled to one end of the data transfer line 14a corresponding to the corresponding column and the other end of the capacitive element 61 is grounded to a constant potential, for example, a reference potential of zero voltage.

The auxiliary circuit 70 is an assembly of a transmission gate 72 provided for each column and an N-channel MOS type transistor 73 provided for each column. Further, the capacitive element group 80 is an assembly of a capacitive element 82 provided for each column.

Here, the input end of the transmission gate 72 of a certain column is coupled to the other end of the data transfer line 14a and the output end of the transmission gate 72 of the corresponding column is coupled to the drain node of the transistor 73 corresponding to the corresponding column and one end of the capacitive element 82 corresponding to the corresponding column.

Further, in each column, the control signal Gref is supplied to the gate node of the transistor 73 and the voltage Vref is applied to the source node of the transistor 73.

The other end of the capacitive element 82 corresponding to a certain column is coupled to one end of the data line 14b corresponding to the corresponding column.

The initialization circuit 50 is an assembly of P-channel MOS type transistors 56 provided for each column. In each example, the control signal /Gini is supplied to the gate node of the transistor 56 and the voltage Vini is applied to the source node of the transistor 56. Further, the drain node of the transistor 56 corresponding to a certain column is coupled to the data line 14b corresponding to the corresponding column.

In this embodiment, one end of the data transfer line 14a is coupled to the output end of the transmission gate 45 and one end of the capacitive element 61 and the other end of the data transfer line 14a is coupled to the input end of the transmission gate 72. Since the display area 100 is located between the auxiliary circuit 70 and the switch group 40 and the capacitive element group 60, the data transfer line 14a passes through the display area 100.

On the other hand, the first data signal supplied to the data transfer line 14a via the transmission gate 45 is supplied to the pixel circuits 110 via the transmission gate 72, the capacitive element 82, and the data line 14b as the second data signal.

Thus, the first data signal output from the data signal output circuit 30 reaches the transmission gate 72 and the capacitive element 82 located on the opposite side with the display area 100 interposed therebetween via the data transfer line 14a, is folded back to be the second data signal, and is supplied to the pixel circuits 110 via the data line 14b.

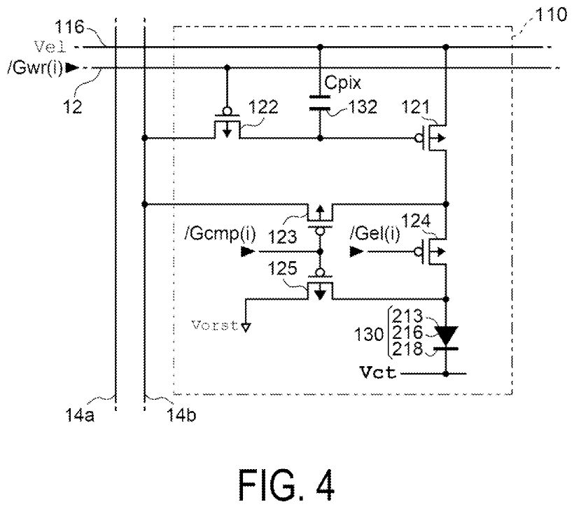

FIG. 4 is a diagram showing a configuration of a pixel circuit 110. The pixel circuits 110 arranged in m rows and 3q columns are electrically identical to each other. Thus, the pixel circuit 110 will be described by using one pixel circuit 110 corresponding to any column in the i-th row as a representative.

As shown in the figure, the pixel circuit 110 includes an OLED 130, P-channel type transistors 121 to 125, and a capacitive element 132.

Further, the control signals /Gel(i) and /Gcmp(i) are supplied from the scanning line drive circuit 120 to the pixel circuit 110 in the i-th row in addition to the scanning signal /Gwr(i).

The OLED 130 is an example of the display element and is an element which sandwiches a light emitting functional layer 216 by a pixel electrode 213 and a common electrode 218 as will be described later. The pixel electrode 213 functions as an anode and the common electrode 218 functions as a cathode. Additionally, the common electrode 218 has optical transparency.

In the OLED 130, when a current flows from the anode to the cathode, holes injected from the anode and electrons injected from the cathode are recombined in the light emitting functional layer 216 to generate excitons and white light. The white light generated at this time resonates in an optical resonator including a reflection film (not shown) and a half mirror and emits at a resonance wavelength set corresponding to one of RGB colors. A color filter corresponding to the color is provided on the light output side from the optical resonator. Thus, the light emitted from the OLED 130 is seen by an observer after being colored by the optical resonator and the color filter.

Additionally, the OLED 130 provided in the pixel circuit 110 is the minimum unit of a display image. One pixel circuit 110 includes one OLED 130. One pixel circuit 110 is controlled independently from the other pixel circuits 110 and the OLED 130 emits a color corresponding to the pixel circuit 110 to express one of three primary colors.

That is, since one pixel circuit 110 expresses one of three primary colors among the colors to be displayed, the pixel circuit should be strictly called a sub-pixel circuit, but the pixel circuit is referred to as a pixel circuit in order to simplify the description. Additionally, the color filter may be omitted when the display device 10 displays only a monochrome image of light and dark.

In the transistor 121, the gate node is coupled to the drain node of the transistor 122, the source node is coupled to the power supply line 116 of the voltage Vel, and the drain node is coupled to the source node of the transistor 123 and the source node of the transistor 124. Additionally, in the capacitive element 132, one end is coupled to the gate node of the transistor 121 and the other end is coupled to the power supply line 116 of the constant voltage, for example, the voltage Vel. Thus, the capacitive element 132 holds the gate voltage of the transistor 121.

Additionally, as the capacitive element 132, a parasitic capacitance on the gate node of the transistor 121 may be used or a capacitance formed by sandwiching an insulating layer between different conductive layers in a silicon substrate may be used.

In the transistor 122 of the pixel circuit 110 in the i-th row and any column, the gate node is coupled to the scanning line 12 in the i-th row and the source node is coupled to the data line 14b of the corresponding column.

In the transistor 123 of the pixel circuit 110 in the i-th row and any column, the control signal /Gcmp(i) is supplied to the gate node and the drain node is coupled to the data line 14b of the corresponding column.

In the transistor 124 of the pixel circuit 110 in the i-th row and any column, the control signal /Gel(i) is supplied to the gate node and the drain node is coupled to the drain node of the transistor 125 and the pixel electrode 213 corresponding to the anode of the OLED 130.

In the transistor 125 of the pixel circuit 110 in the i-th row and any column, the control signal /Gcmp(i) is supplied to the gate node and the source node is coupled to the power supply line of the voltage Vorst.

Additionally, the common electrode 218 functioning as the cathode of the OLED 130 is coupled to the power supply line of the voltage Vct. Further, since the display device 10 is formed on the silicon substrate, the substrate potential of the transistors 121 to 125 is set to, for example, a potential corresponding to the voltage Vel.

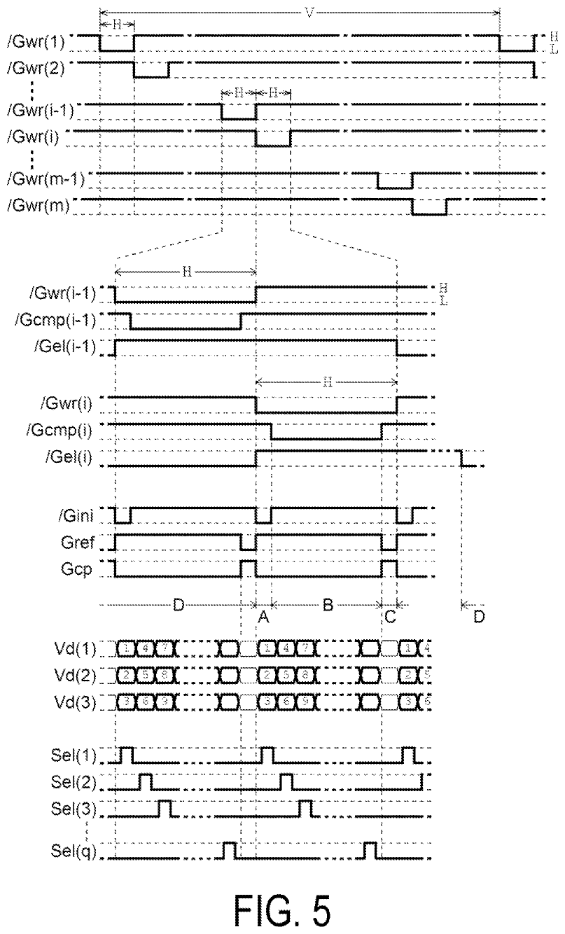

FIG. 5 is a timing chart illustrating an operation of the display device 10.

The display device 10 scans in the order of the first, second, third, . . . , and M-th rows over the period of one frame (F). Specifically, as shown in the figure, the scanning signals /Gwr(1), /Gwr(2), . . . , /Gwr(m−1), and /Gwr(m) switch sequentially and exclusively to the L level for each horizontal scanning period (H) due to the scanning line drive circuit 120.

Additionally, in this description, one frame period is a period required to display one frame of an image designated by the video data Vid. The length of the period of one frame is 16.7 milliseconds corresponding to one cycle of the vertical synchronization signal included in the synchronization signals Sync, for example, when the frequency of the vertical synchronization signal is 60 Hz in the case of the vertical synchronization period. Further, in FIG. 5, the vertical scale indicating the voltage is not necessarily aligned over each signal.

The operation in the horizontal scanning period (H) is common to each row.

Further, the operations of the pixel circuits 110 in the first to (3q)-th columns of the rows scanned in a certain horizontal scanning period (H) are almost the same.

Accordingly, the following description will focus on the pixel circuit 110 in the (3j−2)-th column of the i-th row.

In this embodiment, the horizontal scanning period (H) is mainly divided into three periods: an initialization period (A), a compensation period (B), and a writing period (C). Further, as the operation of the pixel circuit 110, a light emitting period (D) is further added to the three periods.

In the initialization period (A) of each horizontal scanning period (H), the control signal /Gini switches to the L level, the control signal /Gref switches to the H level, and the control signal Gcp switches to the L level. Further, in the compensation period (B), the control signal /Gini switches to the H level, the control signal /Gref is maintained at the H level, and the control signal Gcp is maintained at the L level. In the writing period (C), the control signal /Gini is maintained at the H level, the control signal /Gref switches to the L level, and the control signal Gcp switches to the H level.

Additionally, the light emitting period (D) of the pixel circuit 110 in the i-th row is a period in which the control signal /Gel(i) switches to the L level.

In the horizontal scanning period (H) in which the scanning line 112 of the i-th row is selected, since the scanning signal /Gwr(i) switches to the L level, the transistor 122 of the pixel circuit 110 of the i-th row is turned on. Further, in the horizontal scanning period (H), since the control signal /Gel switches to the H level, the transistor 124 of the pixel circuit 110 is turned off.

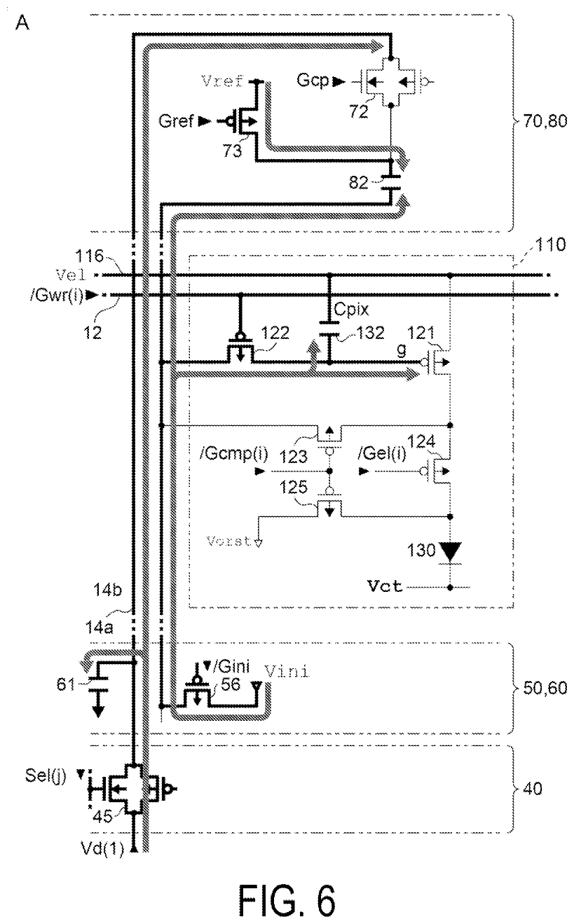

In the initialization period (A) of the horizontal scanning period (H), since the transistor 56 is turned on due to the L level of the control signal /Gini, the data line 14b, the gate node g of the transistor 121, one end of the capacitive element 132, and the other end of the capacitive element 82 are initialized to the voltage Vini as shown in FIG. 6. In the initialization period (A), the transistors 123 and 125 are turned off due to the H level of the control signal /Gcmp(i).

In the initialization period (A), since the transistor 73 is turned on due to the L level of the control signal Gref, the voltage Vref is applied to one end of the capacitive element 82 as shown in FIG. 6.

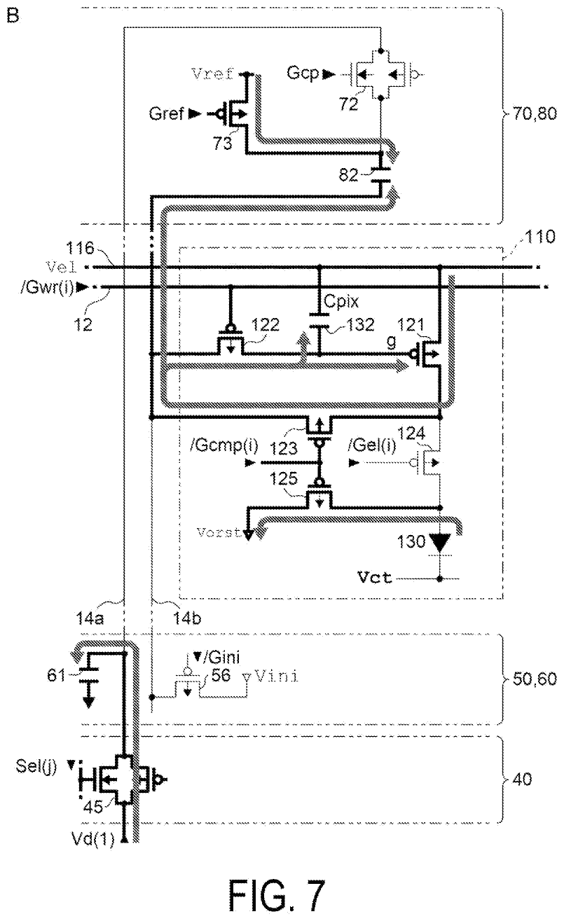

Next, in the compensation period (B) of the horizontal scanning period (H) in which the scanning line 112 of the i-th row is selected, the control signal /Gcmp(i) is at the L level while the scanning signal /Gwr(i) switches to the L level. Thus, in the pixel circuit 110 of the i-th row and the (3j−2)-th column, the transistor 123 is turned on while the transistor 121 is turned on as shown in FIG. 7. Thus, since the gate node and the drain node of the transistor 121 are coupled, that is, the diode is coupled, the voltage between the gate node and the source node of the transistor 121 converges on the threshold voltage of the transistor 121. Additionally, the threshold voltage is referred to as Vth for convenience.

Additionally, in the compensation period (B), since the gate node and the drain node of the transistor 121 are coupled to the data line 14b, the voltage of the data line 14b also becomes the voltage (Vel-Vth) corresponding to the threshold voltage Vth of the transistor 121. In the compensation period (B), since the control signal Gref is at the H level and the transistor 73 is turned on, one end of the capacitive element 82 has the voltage Vref and the other end thereof has the voltage (Vel-Vth).

Further, in the compensation period (B), since the transistor 125 is turned on due to the L level of the control signal /Gcmp(i), the anode (the pixel electrode) of the OLED 130 is reset to the voltage Vorst.

The control signals Sel(1) to Sel(q) switch sequentially and exclusively to the H level in the initialization period (A) and the compensation period (B). Additionally, although not shown in FIGS. 5, 6, and 7, the control signals /Sel(1) to /Sel(q) are synchronized with the control signals Sel(1) to Sel(q) in the initialization period (A) and the compensation period (B) and switch sequentially and exclusively to the L level.

On the other hand, the data signal output circuit 30 outputs the first data signals Vd(1) to Vd(3) of three pixels corresponding to the intersections of the scanning line 12 of the i-th row and the data line 14b belonging to the j-th group, for example, when the control signal Sel(j) of the control signals Sel(1) to Sel(q) has switched to the H level.

On the other hand, the data signal output circuit 30 outputs the first data signals Vd(1) to Vd(3) of three pixels corresponding to the intersections of the scanning line 12 of the i-th row and the data line 14b belonging to the j-th group, for example, when the control signal Sel(j) of the control signals Sel(1) to Sel(q) has switched to the H level. More specifically, the data signal output circuit 30 outputs the first data signal Vd(1) corresponding to the pixel of the i-th row and the (3j−2) column, outputs the first data signal Vd(2) corresponding to the pixel of the i-th row and the (3j−1)-th column, and outputs the first data signal Vd(3) corresponding to the pixel of the i-th row and the (3j)-th column in a period in which the control signal Sel (j) switches to the H level.

As a detailed example, when j is “2”, the data signal output circuit 30 outputs the first data signal Vd(1) corresponding to the pixel of the i-th row and the fourth column, outputs the first data signal Vd(2) corresponding to the pixel of the i-th row and the fifth column, and outputs the first data signal Vd(3) corresponding to the pixel of the i-th row and the sixth column in a period in which the control signal Sel(2) switches to the H level.

In this way, when the control signals Sel(1) to Sel(q) switch sequentially and exclusively to the H level, the voltage of the first data signal corresponding to each pixel is held by each of the capacitive elements 61 corresponding to the first column to the (3q)-th column.

Additionally, FIG. 6 shows a state in which the control signal Sel(j) corresponding to the j-th group including the pixel circuit 110 switches to the H level in the initialization period (A) and the voltage of the first data signal Vd(1) is held by the capacitive element 61.

Further, FIG. 7 shows a state in which the control signal Sel(j) corresponding to the j-th group switches to the H level in the compensation period (B) and the voltage of the first data signal Vd(1) is held by the capacitive element 61.

Next, in the writing period (C) of the horizontal scanning period (H) in which the scanning line 112 of the i-th row is selected, the control signal /Gcmp(i) becomes the H level while the scanning signal /Gwr(i) is at the L level. Thus, in the pixel circuit 110 of the i-th row and the (3j−2)-th column, the transistors 123 and 125 are turned off.

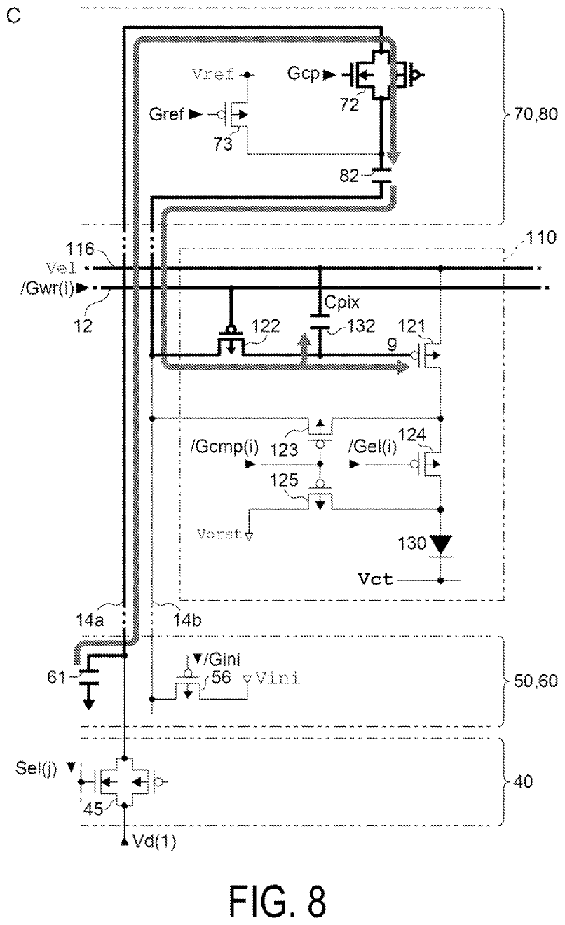

Further, in the writing period (C), since the control signal Gref becomes the L level as shown in FIG. 8, the transistor 73 is turned off. Further, since the control signal Gcp becomes the H level (the control signal /Gcp becomes the L level), the transmission gate 72 is turned on. Thus, one end of the capacitive element 82 changes from the voltage Vref to the voltage held by a holding capacitance 81. A change in the voltage is transmitted to the data line 14b and the gate node g via the capacitive element 82.

Here, when the capacitance of the capacitive element 82 is indicated by Crf1 and the parasitic capacitance of the data line 14b is indicated by Cdt, the gate node g in the pixel circuit 110 changes from the voltage (Vel-Vth) by an amount obtained by multiplying the voltage change amount at one end of the capacitive element 82 by the ratio of the capacitance Crf1 with respect to the sum of the capacitances Crf1 and Cdt and the voltage of the gate node g after the change is held by the capacitive element 132.

Although the above-described ratio should also consider the capacitance of the capacitive element 132, the capacitance of the capacitive element 132 can be ignored when the capacitance is sufficiently smaller than the capacitances Crf1 and Cdt.

After the writing period (C) ends, the light emitting period (D) starts. That is, since the control signal /Gel(i) is inverted to the L level when the light emitting period (D) is reached after the selection of the scanning line 12 of the i-th row ends, the transistor 124 is turned on. Thus, a current corresponding to the voltage Vgs held by the capacitive element 132 flows to the OLED 130 and the OLED 130 emits light with a brightness corresponding to the current.

Additionally, FIG. 5 shows an example in which the light emitting period (D) is continued after the selection of the scanning line 12 of the i-th row ends, but a period in which the control signal /Gel(i) is at the L level may be intermittent or may be adjusted in response to the brightness adjustment. Further, the level of the control signal /Gel (i) in the light emitting period (D) may be larger than the L level in the compensation period (B). That is, the level between the H level and the L level may be used as the level of the control signal /Gel(i) in the light emitting period (D).

As described above, in the interested pixel circuit 110, the voltage Vgs between the gate and the source in the writing period (C) and the light emitting period (D) is the voltage changed from the voltage (Vel-Vth) in the compensation period (B) in response to the gradation level of the pixel circuit 110. Since the same operation is also performed in the other pixel circuit 110, in this embodiment, a current corresponding to the gradation level flows to the OLED 130 while the threshold voltage of the transistor 121 is compensated over all pixel circuits 110 of the m-th row and the (3q)-th column. Thus, in this embodiment, high-quality display can be realized as a result of less variation in brightness.

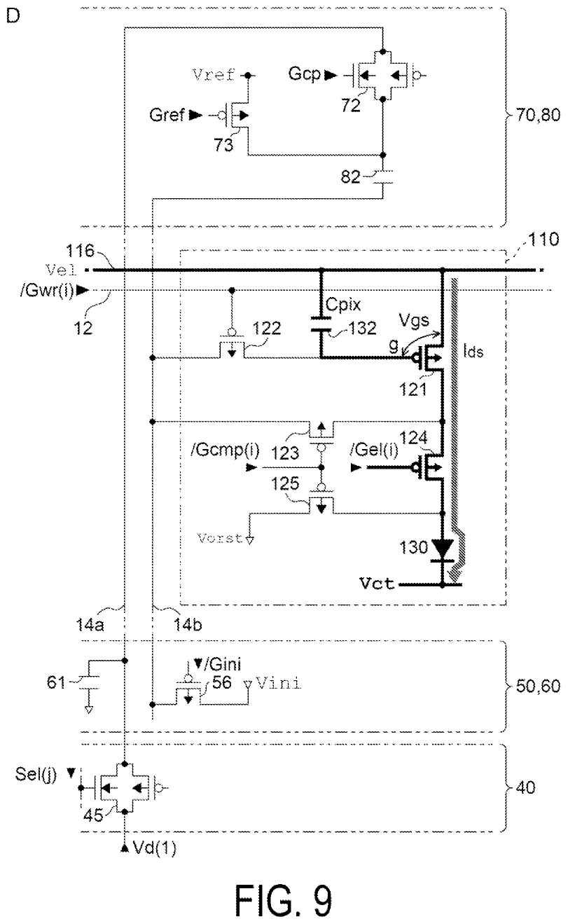

Additionally, in FIGS. 6 to 9, the area provided with the initialization circuit 50 and the capacitive element group 60 is not particularly distinguished. Similarly, the area provided with the auxiliary circuit 70 and the capacitive element group 80 is not particularly distinguished.

In the embodiment, the display area 100 is located between the data signal output circuit 30 and the capacitive element 82 coupled to one end of the data line 14b.

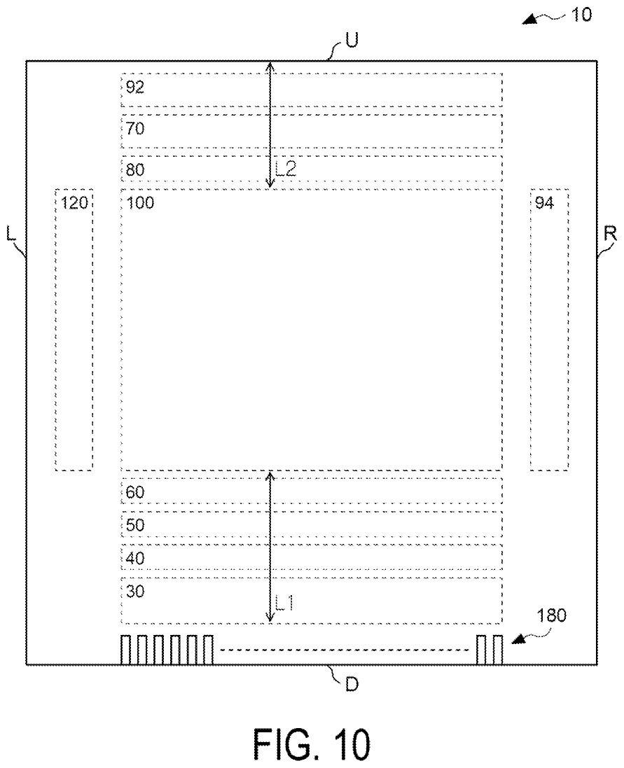

More specifically, when the upper side is indicated by U, the lower side is indicated by D, the left side is indicated by L, and the right side is indicated by R in the rectangular display device 10 as shown in FIG. 10, an inspection circuit 92, the auxiliary circuit 70, and the capacitive element group 80 are provided between the upper side U and the display area 100 in this order from the upper side U.

Further, a terminal 180, the data signal output circuit 30, the switch group 40, the initialization circuit 50, and the capacitive element group 60 are provided between the lower side D and the display area 100 in this order from the lower side D.

The scanning line drive circuit 120 is provided between the left side L and the display area 100 and the inspection circuit 94 is provided between the right side R and the display area 100.

Additionally, the inspection circuit 92 is provided to inspect the data signal output circuit 30 or the like after production and the inspection circuit 94 is provided to inspect the scanning line drive circuit 120 after production.

In this embodiment, the display area 100 is located between the data signal output circuit 30 and the auxiliary circuit 70 and the capacitive element group 80.

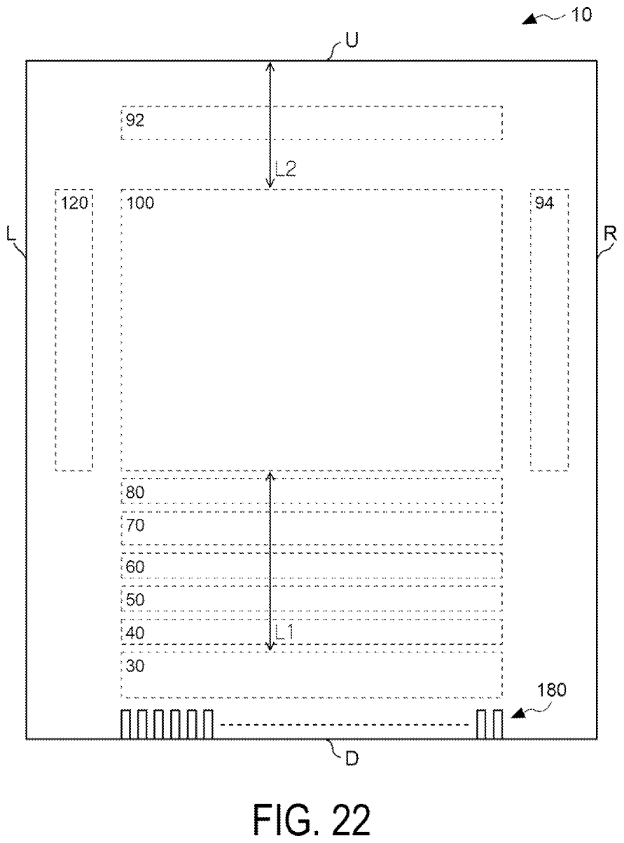

From the viewpoint of shortening the signal path from the data signal output circuit 30 to the data line 14b, the data signal output circuit 30, the switch group 40, the initialization circuit 50, the capacitive element group 60, the auxiliary circuit 70, the capacitive element group 80, and the display area 100 may be disposed in this order as shown in FIG. 22.

Additionally, in FIG. 22, the distance from the data signal output circuit 30 to the display area 100 is indicated by L1.

In the arrangement shown in FIG. 22, since the auxiliary circuit 70 and the capacitive element group 80 do not exist between the upper side U and the display area 100 compared to the arrangement shown in FIG. 10, the distance L2 from the upper side U to the display area 100 can be shortened.

However, in reality, the distance from each side to the display area 100 should be ensured to some extent because of the accuracy of film formation in the light emitting functional layer 216. Specifically, there is a situation in which the distance L2 from the upper side U to the display area 100 cannot be shortened more than necessary.

Here, such circumstances will be described.

As described above, the OLED 130 has a configuration in which the light emitting functional layer 216 is sandwiched between the pixel electrode 213 of the anode and the common electrode 218 of the cathode. The pixel electrode 213, the light emitting functional layer 216, and the common electrode 218 are formed in this order.

Further, since the common electrode 218 is required to be transparent as described above, ITO (Indium Tin Oxide), an alloy containing magnesium and silver, or the like is used. The voltage Vct is applied to the common electrode 218 and the common electrode 218 is common to all OLEDs 130.

The light emitting functional layer 216 which is formed before the common electrode 218 is electrically a semiconductor. Thus, the common electrode 218 is formed to cover the light emitting functional layer 216. On the other hand the plurality of terminals 180 are formed by patterning a conductive layer having a low resistivity.

Thus, it is important to uniformly reduce the wiring resistance from one or more specific terminals of the plurality of terminals 180 to the common electrode 218 formed in a layer different from the layer in which the terminals are formed.

The light emitting functional layer 216 is not formed for each pixel circuit 130, but is continuously formed over all pixel circuits 110. Thus, an area in which the pixel electrode 213 and the common electrode 218 overlap each other in a plan view, that is, an area in which a current flows from the pixel electrode 213 to the common electrode 218 functions as the OLED 130.

The light emitting functional layer 216 is formed, for example, through a metal mask including the display area 100 and opening in an area wider than the display area 100. Thus, the light emitting functional layer 216 has a lower position accuracy of film formation and a larger production error than other layers, specifically, layers formed by photolithography.

As described above, the common electrode 218 needs to cover the light emitting functional layer 216, but it should be noted that the positional accuracy when forming the light emitting functional layer 216 is low.

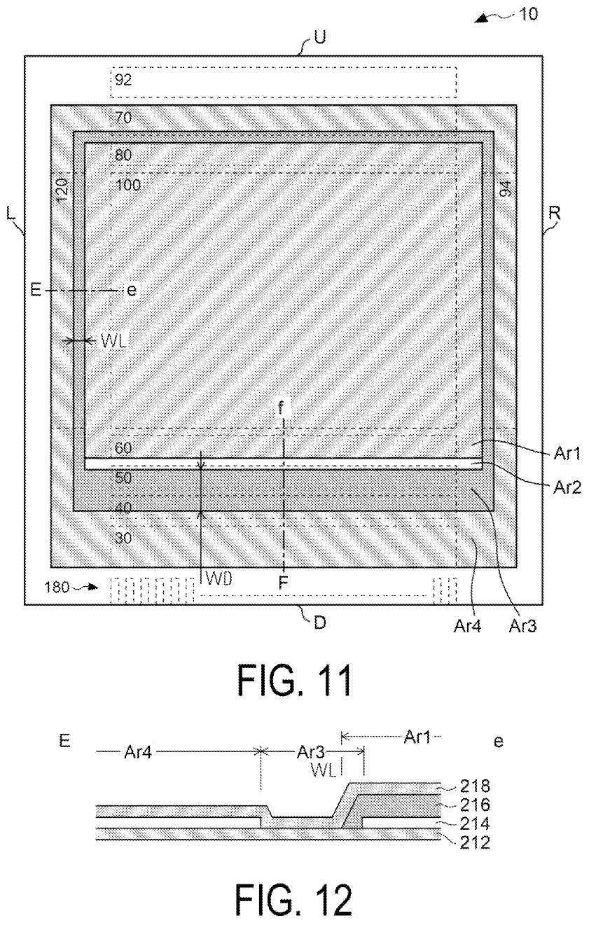

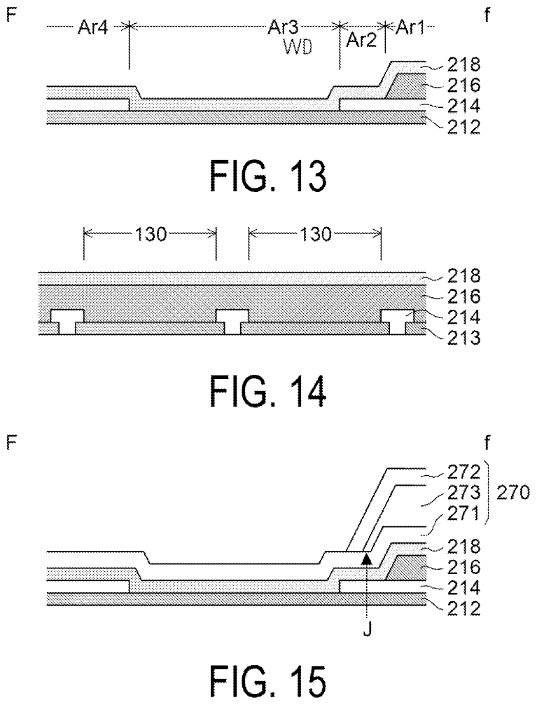

FIG. 11 is a plan view showing the arrangement of the light emitting functional layer 16, the opening of the opening defining layer, and the common electrode 218, FIG. 12 is a partially cross-sectional view when taken along a line E-e of FIG. 11, FIG. 13 is a partially cross-sectional view when taken along a line F-f of FIG. 11, and FIG. 14 is a cross-sectional view of a main part of the OLED 130 in the display device 10.

Additionally, the display device 10 is provided with transistors constituting the data signal output circuit 30, the scanning line drive circuit 120, and the like, but in FIGS. 12 to 14, a wiring layer, an insulating layer, and the like corresponding to the layers lower than the pixel electrode 213 which is the cathode are not shown.

In FIG. 11, an area Ar1 is an area provided with the light emitting functional layer 216 in a plan view and includes the display area 100 and is wider than the display area 100 as described above.

An area Ar3 is an opening outside the display area 100 in the opening in the opening defining layer 214 in a plan view. The opening defining layer 214 is formed between the conductive layer 212 and the light emitting functional layer 216 by using an insulating inorganic material such as silicon nitride or silicon oxide. In the opening defining layer 214, the opening outside the display area 100 is formed in a frame shape in a plan view.

Thus, when the common electrode 218 is formed after forming the conductive layer 212 and the opening defining layer 214 in this order, the conductive layer 212 and the common electrode 218 are electrically coupled in the area Ar3 corresponding to the opening of the opening defining layer 214 outside the display area 100.

The conductive layer 212 is formed by patterning a metal layer of aluminum or the like, is formed in the same layer (or a different layer) as a specific terminal in the plurality of terminals 180, and is electrically coupled to the specific terminal. Thus, the voltage Vct is applied to the common electrode 218 via the specific terminal, the conductive layer 212, and the area Ar3.

Additionally, an area Ar4 means an area outside the area Ar3 having a frame shape in a plan view in the area provided with the common electrode 218. The area Ar2 is an area which is outside the display area 100 and inside the frame-shaped area Ar3 in a plan view.

The opening defining layer 214 functions as a layer that defines the shape of the OLED 130 in a plan view between the pixel electrode 213 and the light emitting functional layer 216 as shown in FIG. 14 in the display area 100. Further, the pixel electrode 213 may be formed by patterning the same layer as the conductive layer 212 or may be formed by patterning a layer different from the conductive layer 212.

As described above, since the positional accuracy when forming the light emitting functional layer 16 is low, the light emitting functional layer 216 is caught by the end of the opening defining layer 214 as shown in FIG. 12 and the light emitting functional layer 216 is not caught by the end of the opening defining layer 214 as shown in FIG. 13 when the opening defining layer 214 is used as a reference.

As shown in FIG. 12, when the light emitting functional layer 216 is caught by the end of the opening defining layer 214, the opening of the opening defining layer 214 is eroded and the electrical coupling distance between the conductive layer 212 and the common electrode 218 is narrowed. Thus, a sufficiently low contact resistance is obtained and the voltage Vct is not uniformly applied to the common electrode 218, so that the display quality is deteriorated.

Thus, it is necessary to ensure the width of the area Ar3 for the contact between the common electrode 218 and the conductive layer 212 to a certain extent or more outside the display area 100 even when the accuracy when forming the light emitting functional layer 216 is poor. Additionally, the width of the area Ar3 is the distance of the opening in the opening defining layer 214, specifically, a distance WL in a portion along the left side L and a distance WD in a portion along the lower side D.

In the display device 10, since the auxiliary circuit 70 and the capacitive element group 80 are provided between the upper side U and the display area 100, the distance L1 from the data signal output circuit 30 to the display area 100 can be shortened compared to the distance L1 in the case of FIG. 22. Thus, in this embodiment, since the distance L1 is shortened while the distance L2 is the same in order to ensure the area Ar3, the display device 10 can be decreased in size.

### MODIFIED EXAMPLES, APPLICATION EXAMPLES, ETC.

The above-described embodiments can be applied or modified as below.

### First Modified Example

When a sealing layer 270 is provided to cover the light emitting functional layer 216 in the display device 10, the position of the edge of the constituent layer of the sealing layer 270 may be determined as described below. FIG. 15 corresponds to a partially cross-sectional view when the display device 10 is broken along a line F-f of FIG. 11. As shown in this drawing, in the sealing layer 270, a first inorganic layer 271, an intermediate layer 273, and a second inorganic layer 272 are laminated in this order.

The first inorganic layer 271 of the sealing layer 270 is formed on the surface of the common electrode 218 and directly contacts the surface of the common electrode 218. The first inorganic layer 271 is formed over the entire area of the display device 10 including the display area 100. The first inorganic layer 271 is formed of an insulating and transparent inorganic material such as a silicon compound (typically, silicon nitride or silicon oxide) and is formed to have a film thickness of, for example, about 200 nm to 400 nm.

The intermediate layer 273 is an element that seals the light emitting functional layer 16 and is formed of a light transmissive organic material such as an epoxy resin. The edge J of the intermediate layer 273 is located outside the light emitting functional layer 216 and inside the area Ar3 in a plan view. The intermediate layer 273 also functions as a flattening film that fills the steps of the surfaces of the common electrode 218 and the first inorganic layer 271 in the display area 100. Thus, the intermediate layer 273 is formed to have a sufficiently thick film thickness (for example, 1 m to 5 m, particularly preferably 3 m) as compared with the first inorganic layer 271 and the second inorganic layer 272. Additionally, the material of the intermediate layer 273 is not limited to the organic material.

The second inorganic layer 272 is an element that seals the intermediate layer 273. Thus, the edge of the second inorganic layer 272 is located outside the intermediate layer 273 and inside the area Ar3 in a plan view. The second inorganic layer 272 is formed of, for example, an inorganic material which is excellent in water resistance and heat resistance and has an insulating property and transparency to have a film thickness, for example, about 300 nm to 700 nm (particularly preferably about 400 nm). For example, a nitrogen compound (silicon nitride, silicon oxide, silicon oxynitride) is suitable as a material for the second inorganic layer.

Since the film thickness of the intermediate layer 273 is thicker than those of the first inorganic layer 271 and the second inorganic layer 272, the positional accuracy of film formation of the intermediate layer 273 is low. However, according to the first modified example, it is possible to ensure a function of sealing the light emitting functional layer 216 when the edge J of the intermediate layer 273 is outside the light emitting functional layer 16 in a plan view.

### Second Modified Example

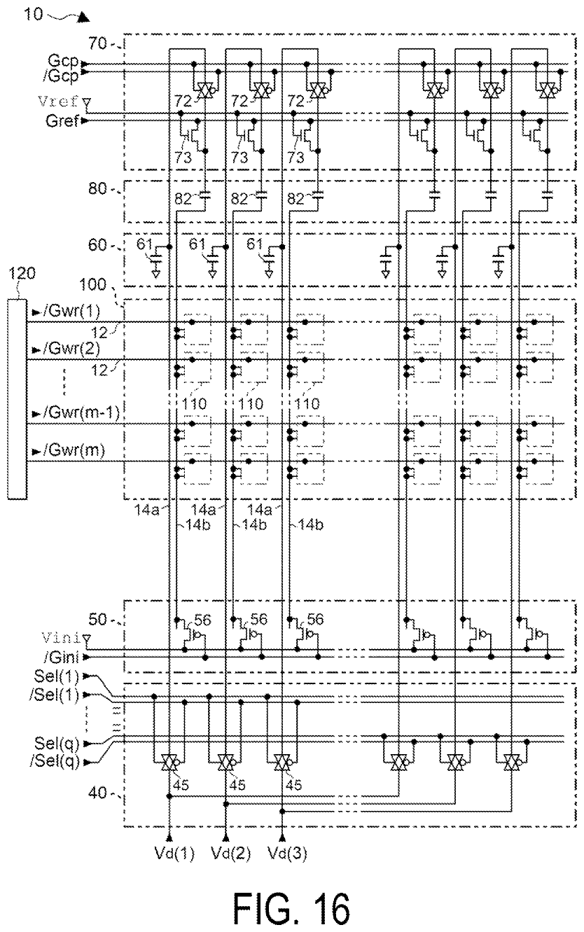

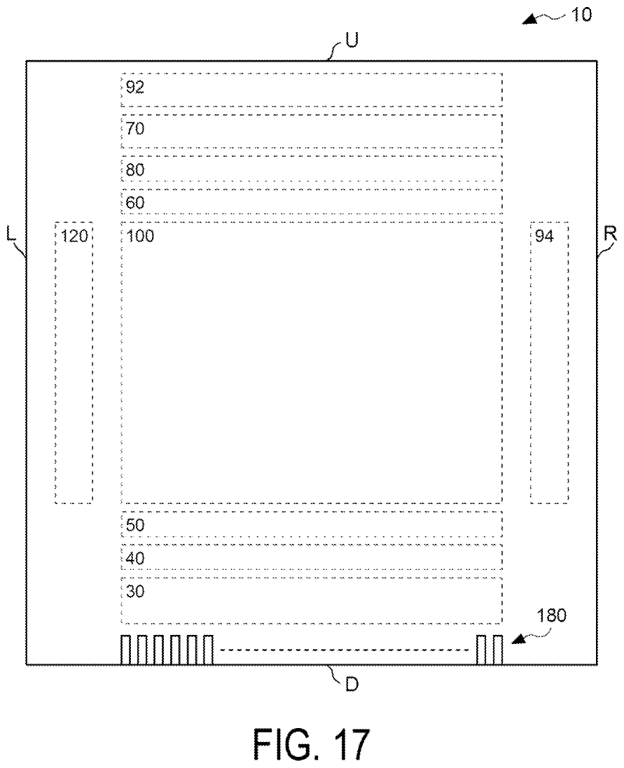

In the embodiment, the capacitive element group 60 is provided between the data signal output circuit 30 and the display area 100 as shown in FIG. 10, but the position of the capacitive element group 60 is not limited to that of FIG. 10. For example, the capacitive element group 60 may be provided between the auxiliary circuit 70 and the display area 100 as shown in FIGS. 16 and 17.

Additionally, FIG. 16 is a part of the circuit diagram of the display device 10 and is electrically equivalent to FIG. 3. Further, FIG. 17 is a plan view showing the arrangement of the elements of the display device 10.

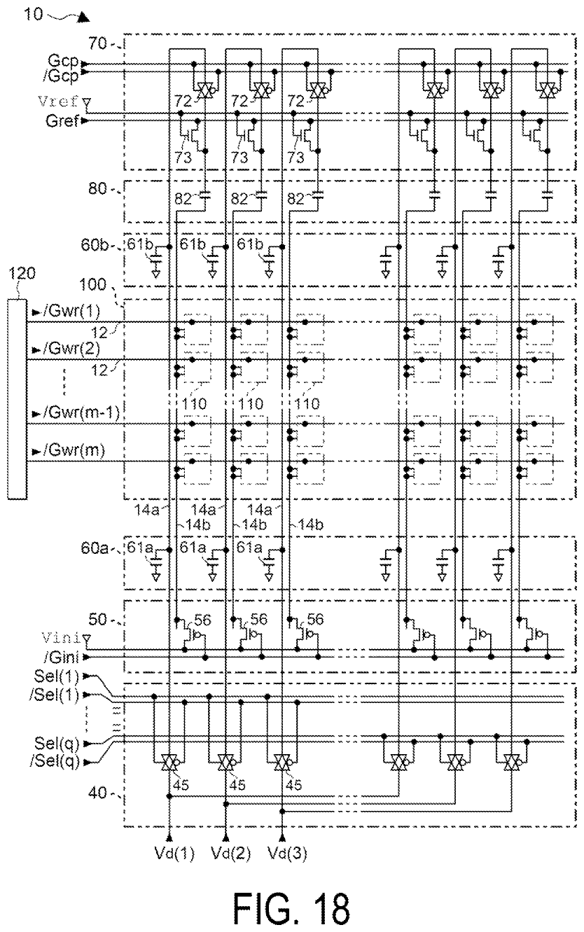

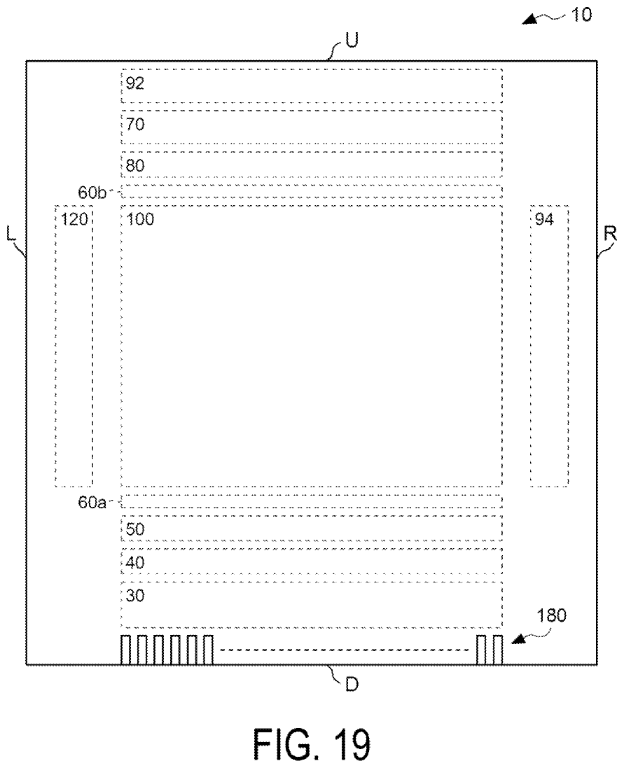

Further, one capacitive element 61 in the capacitive element group may be divided into capacitive element 61a and 61b as shown in FIG. 18. Then, as shown in FIG. 19, a capacitive element group 60a which is an assembly of the capacitive element 61a may be provided between the data signal output circuit 30 and the display area 100 and a capacitive element group 60b which is an assembly of the capacitive element 61b may be provided between the auxiliary circuit 70 and the display area 100.

### OTHER EXAMPLES

In the embodiment, an example in which three-phase conversion is performed by serial-parallel conversion has been shown, but the number of phases may be two or more.

Further, instead of the serial-parallel conversion, for example, the data signal output circuit 30 may output the first data signal which is an analog and uncompressed state in a dot-sequential manner and the transmission gate 45 constituting the switch group 40 may be configured to sample the analog signal in a dot-sequential manner. In this configuration, the shift register 31 and the latch circuit 32 are unnecessary.

If the drive capability of the D/A converter is high, the amplifier group 34 may not be provided.

Although the display device 10 is configured to compensate the threshold value of the transistor 121 of the pixel circuit 110, the threshold value may not be compensated. Specifically, the transistor 123 may be omitted.

Further, In the embodiment, the OLED 130 has been described as an example of the display element, but another display element may be used. For example, a liquid crystal element may be used as the display element. The liquid crystal element may also be formed on a semiconductor substrate such as a silicon substrate. Also in this case, a voltage applied to the liquid crystal element needs to be compressed and supplied via the capacitive element.

The channels of the transistors 56, 73, 121 to 125 are not limited to the embodiment. Further, these transistors 56, 73, 121 to 125 may be replaced with transmission gates as appropriate. On the contrary, the transmission gates 45 and 72 may be replaced with one-channel transistors.

Electronic Apparatus

Next, an electronic apparatus that adopts the display device 10 according to the embodiment will be described. The display device 10 is suitable for a high-definition display with a small pixel size. Here, as an electronic apparatus, a head mounted display will be described as an example.

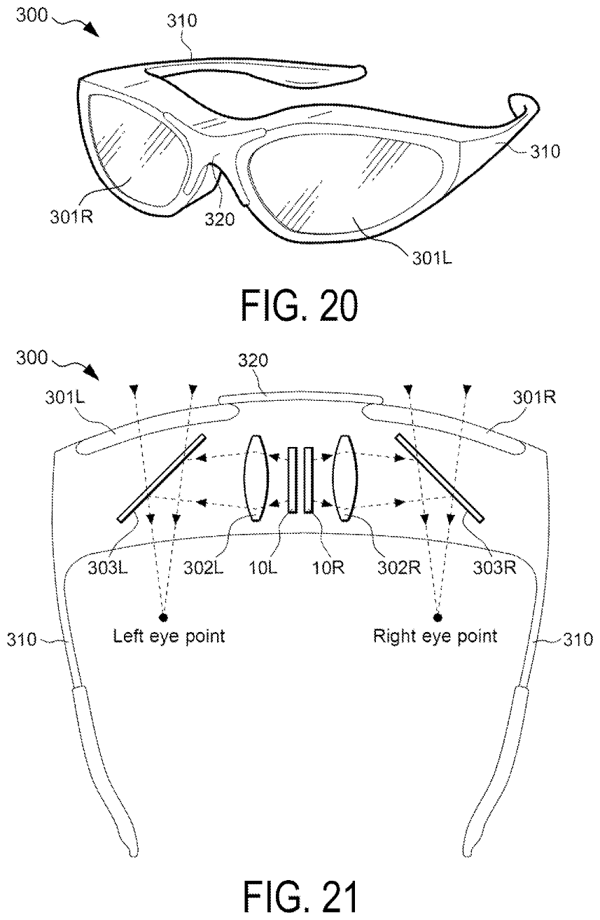

FIG. 20 is a diagram showing the upper side of the head mounted display and FIG. 21 is a diagram showing an optical configuration thereof.

First, as shown in FIG. 20, a head mounted display 300 includes a temple 310, a bridge 320, and lenses 301L and 301R in appearance similar to general glasses. Further, the head mounted display 300 includes a display device 10L for the left eye and a display device 10R for the right eye on the back side (lower side in the figure) of the lenses 301L and 301R near the bridge 320 as shown in FIG. 21.

The image display surface of the display device 10L is disposed on the left side in FIG. 21. Accordingly, the image displayed by the display device 10L is emitted in the 9 o'clock direction in the figure via an optical lens 302L. A half mirror 303L reflects the image displayed by the display device 10L in the 6 o'clock direction and transmits the light incident from the 12 o'clock direction. The image display surface of the display device 10R is disposed on the right side opposite to the display device 10L. Accordingly, the image displayed by the display device 10R is emitted in the 3 o'clock direction in the figure via the optical lens 302R. A half mirror 303R reflects the image displayed by the display device 10R in the 6 o'clock direction and transmits the light incident from the 12 o'clock direction.

In this configuration, the wearer of the head mounted display 300 can observe the images displayed by the display devices 10L and 10R in a see-through state in which the display images are superposed on the outside.

Further, in the head mounted display 300, when the image for the left eye of the binocular images with parallax is displayed on the display device 10L and the image for the right eye thereof is displayed on the display device 10R, it is possible to make the wearer perceive the displayed image as if the image has a depth and a three-dimensional effect.

Additionally, the electronic apparatus including the display device 10 can be applied to not only the head mounted display 300 but also an electronic viewfinder in a video camera, a lens-interchangeable digital camera, or the like.

### APPENDIX

A display device according to one aspect (Aspect 1) includes: a display area including a pixel circuit provided at an intersection between a scanning line and a data line; a data signal output circuit configured to output a data signal; and a first capacitive element including one end and the other end and is configured such that, the one end being supplied with the first data signal, and the other end being coupled to the data line, wherein the pixel circuit includes a display element which has an optical state based on the data signal supplied to the data line and the display area is provided between the first capacitive element and the data signal output circuit.

According to this aspect, since the display area is provided between the first capacitive element and the data signal output circuit, it is possible to reduce the area provided with the data signal output circuit and the like in the outer area of the display area. Thus, the display device can be decreased in size.

Additionally, the capacitive element 82 is an example of the first capacitive element. Further, the optical state specifically means a state having a transmittance or a reflectance to emit light with a brightness based on a data signal.

The display device according to a specific aspect (Aspect 2) of Aspect 1 includes: a data transfer line; a second capacitive element which holds a voltage of the data transfer line; a first switching element which is provided between the data signal output circuit and the data transfer line; and a second switching element which is provided between the data transfer line and the first capacitive element, wherein the data signal is output to the data line via the first switching element, the data transfer line, the second switching element, and the first capacitive element in this order.

According to this aspect, the data signal can be held by the second capacitive element by turning on the first switching element. Additionally, the capacitive element 61 is an example of the second capacitive element. Further, the transmission gate 45 is an example of the first switching element and the transmission gate 72 is an example of the second switching element.

In the display device according to a specific aspect (Aspect 3) of Aspect 2, the data signal output circuit outputs the data signal while the first switching element is on and the second switching element is turned off in a first period and the first switching element is turned off and the second switching element is turned on in a second period after the first period.

According to this aspect, the data signal held by the second capacitive element can be supplied to the data line via the first capacitive element by turning on the second switching element. Additionally, the initialization period or the compensation period is an example of the first period and the writing period is an example of the second period.

The display device according to a specific aspect (Aspect 4) of anyone of Aspects 1 to 3, further including: a conductive layer; a common electrode; and an opening defining layer which is provided between the conductive layer and the common electrode and has an insulating property, wherein the pixel circuit includes a display element in which a light emitting functional layer is provided between a pixel electrode and the common electrode and the common electrode is electrically coupled to the conductive layer in the opening.

According to this aspect, since it is possible to ensure an area where the conductive layer is electrically coupled to the common electrode even when the positional accuracy when forming the light emitting functional layer is low, it is possible to reduce the resistance of the common electrode by reducing the contact resistance.

In the display device according to a specific aspect (Aspect 5) of Aspect 4, the light emitting functional layer is covered with the common electrode. According to this aspect, since the light emitting functional layer is covered with the common electrode, the common electrode functions as a kind of sealing.

An electronic apparatus according to a specific aspect (Aspect 6) of Aspects 1 to 4 includes: the display device according to any one of Aspects. According to this aspect, since the display device can be easily decreased in size, the electronic apparatus also can be easily decreased in size.

What is claimed is:

1. A display device comprising:
a display area including a pixel circuit disposed to correspond to an intersection between a scanning line and a data line;
a data signal output circuit configured to output a first data signal; and
a first capacitive element including one end and another end, the one end being supplied with the first data signal, and the other end being coupled to the data line, wherein
the display area is disposed between the first capacitive element and the data signal output circuit in plan view.

2. The display device according to claim 1, further comprising:
a data transfer line supplied with the first data signal;
a first switching element provided between the data signal output circuit and the data transfer line; and
a second switching element provided between the data transfer line and the first capacitive element, wherein
the first data signal is supplied to the one end of the first capacitive element via the first switching element, the data transfer line, and the second switching element in this order, and
the data line is supplied with a second data signal corresponding to the first data signal.

3. The display device according to claim 2, further comprising:
a second capacitive element which holds a potential of the data transfer line, wherein
the data signal output circuit outputs the first data signal in a state where the first switching element is ON and the second switching element is OFF, in a first period, and
the first switching element is OFF state and the second switching element is ON state, in a second period after the first period.

4. The display device according to claim 1, further comprising:
a conductive layer;
a common electrode; and
an opening defining layer that is provided between the conductive layer and the common electrode and that has an insulating property, the opening defining layer including an opening, wherein
the pixel circuit includes a display element having a light emitting functional layer provided between a pixel electrode and the common electrode, and
the common electrode is electrically coupled to the conductive layer at the opening.

5. The display device according to claim 4, wherein
the light emitting functional layer is covered with the common electrode.

6. An electronic apparatus comprising the display device according to claim 1.
